(19) United States
(12) Patent Application Publication
(10) Pub. No.: US 2015/0137201 A1
(43) Pub. Date: May 21, 2015

(54) HIGH DENSITY LINEAR CAPACITOR

(71) Applicant: QUALCOMM Incorporated, San Diego, CA (US)

(72) Inventors: Bruce Sokki LEE, Irvine, CA (US); Seyfollah Seyfollahi BAZARJANI, San Diego, CA (US); Liang DAI, San Diego, CA (US)

(73) Assignee: QUALCOMM Incorporated, San Diego, CA (US)

(21) Appl. No.: 14/264,620

(22) Filed: Apr. 29, 2014

Related U.S. Application Data
(60) Provisional application No. 61/906,834, filed on Nov. 20, 2013.

(51) Int. Cl. H01L 27/06; H01L 49/02

(52) U.S. Cl. CPC H01L 27/0629; H01L 28/40
USPC 257/296; 438/250; 438/393; 257/532

(57) ABSTRACT

A methods for fabricating a capacitor structure includes fabricating polysilicon structures on a semiconductor substrate. The method further includes fabricating M1 to diffusion (MD) interconnects on the semiconductor substrate. The polysilicon structures are disposed in an interleaved arrangement with the MD interconnects. The method also includes selectively connecting the interleaved arrangement of the MD interconnects and/or the polysilicon structures as the capacitor structure.

### CROSS REFERENCE TO RELATED APPLICATION

The present disclosure claims the benefit of U.S. Provisional Patent Application No. 61/906,834, entitled “HIGH DENSITY LINEAR CAPACITOR,” filed on Nov. 20, 2013, the disclosure of which is expressly incorporated by reference herein in its entirety.

### BACKGROUND

1. Field

Aspects of the present disclosure relate to semiconductor devices, and more particularly to capacitors in semiconductor structures.

2. Background

In mixed-signal/radio frequency (RF) circuits, linear capacitors with an increased density are desired to reduce area. Metal capacitors, such as rotated metal-oxide-metal (RTMOM) and finger metal-oxide-metal (FMOM), may be used. Their density, however, is much lower than that of metal-oxide-semiconductor (MOS) capacitors, which are non-linear.

### SUMMARY

A method for fabricating a capacitor structure includes fabricating polysilicon structures on a semiconductor substrate. The method further includes fabricating M1 to diffusion (MD) interconnects on the semiconductor substrate. The polysilicon structures are disposed in an interleaved arrangement with the MD interconnects. The method also includes selectively connecting the interleaved arrangement of the MD interconnects and/or the polysilicon structures as the capacitor structure.

A capacitor structure includes polysilicon structures on a semiconductor substrate. The structure also includes M1 to diffusion (MD) interconnects on the semiconductor substrate. The polysilicon structures are disposed in an interleaved arrangement with the MD interconnects. The MD interconnects and/or the polysilicon structures are selectively connected in the interleaved arrangement as the capacitor structure.

A capacitor structure includes polysilicon structures on a semiconductor substrate. The capacitor structure includes means for interconnecting a conducting layer to an oxide diffusion region on the semiconductor substrate. The polysilicon structures are disposed in an interleaved arrangement with the interconnecting means. The polysilicon structures and/or the interconnecting means are selectively connected in the interleaved arrangement as the capacitor structure.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates a FinFET structure in accordance with an aspect of the present disclosure.

FIG. 2 illustrates a capacitor structure in accordance with an aspect of the present disclosure.

FIG. 3 illustrates a capacitor structure in accordance with another aspect of the present disclosure.

FIG. 4 is a process flow diagram illustrating a method for fabricating a capacitor structure according to an aspect of the present disclosure.

FIG. 5 is a block diagram showing an exemplary wireless communication system in which a configuration of the disclosure may be advantageously employed.

FIG. 6 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Capacitors are passive elements used in integrated circuits for storing an electrical charge. Capacitors are often made using plates or structures that are conductive with an insulating material between the plates. The amount of storage, or capacitance, for a given capacitor is contingent upon the materials used to make the plates and the insulator, the area of the plates, and the spacing between the plates. The insulating material is often a dielectric material.

Capacitors can consume a large area on a semiconductor chip because many designs place the capacitor over the substrate of the chip. This approach takes up a large amount of substrate area, which reduces the available area for active devices. Another approach is to create a vertical structure, which may be known as a vertical parallel plate (VPP) capacitor. The VPP capacitor structure may be created through stacking of the metal layers on the chip. VPP structures, however, have lower capacitive storage, or lower “density,” in that these structures do not store much electrical charge. The interconnect and via layer conductive traces are very small in size. The spacing between the interconnect and via layer conductive traces in VPP structures is limited by design rules, which often results in a large area in order to achieve certain desired capacitance for such structures. Although described as “vertical” these structures can be in any direction that is substantially perpendicular to the surface of the substrate, or at other angles that are not substantially parallel to the substrate using a semiconductor fabrication process.

Semiconductor fabrication processes are often divided into three parts: a front end of line (FEOL), a middle of line (MOL) and a back end of line (BEOL). Front end of line processes include wafer preparation, isolation, well formation, gate patterning, spacers, and dopant implantation. A middle of line process includes gate and terminal contact formation. The gate and terminal contact formation of the middle of line process, however, is an increasingly challenging part of the fabrication flow, particularly for lithography patterning. Back end of line processes include forming interconnects and dielectric layers for coupling to the FEOL devices. These interconnects may be fabricated with a dual damascene process using plasma-enhanced chemical vapor deposition (PECVD) deposited interlayer dielectric (ILD) materials.

More recently, the number of interconnect levels for circuitry has substantially increased due to the large number of transistors that are now interconnected in a modern microprocessor. The increased number of interconnect levels for supporting the increased number of transistors involves more intricate middle of line processes to perform the gate and terminal contact formation.

In particular, advances in lithography have reduced line spacing to less than twenty (20) nanometers on integrated circuit chips. The use of these reduced line spacing increases the available area for capacitance because more lines of charge storage can be placed in the same volume of material. Further, the use of middle of line interconnect structures, as described in one aspect of the present disclosure, allows for an improved capacitor structure.

As described herein, the middle of line interconnect layers may refer to the conductive interconnects for connecting a first conductive layer (e.g., metal 1 (M1)) to an oxide diffusion (OD) layer of an integrated circuit as well for connecting M1 to the active devices of the integrated circuit. The middle of line interconnect layers for connecting M1 to the OD layer of an integrated circuit may be referred to as “MD1” and “MD2,” collectively referred to herein as “MD interconnects.” The middle of line interconnect layer for connecting M1 to the polysilicon gates of an integrated circuit may be referred to as “MP,” or “MP interconnects.”

One aspect of the present disclosure describes a method to construct a linear capacitor using FinFET technology. In one configuration, a capacitance density of the linear capacitor is increased by using both M1 to diffusion (MD) interconnects and polysilicon structures. One aspect of the present disclosure describes a MD-MD capacitor with a floating polysilicon structure between the MD interconnects. The MD-MD capacitor has a higher density than RTMOM/FMOM structures, and may also have a higher voltage tolerance and Q-factor. Another aspect of the present disclosure describes an MD-polysilicon capacitor that may have an even higher density than the MD-MD capacitor of the present disclosure, but may have a lower voltage tolerance and a lower Q-factor. These aspects of the present disclosure make use of the MD interconnects and the polysilicon structures within the layout design constraints, while meeting higher density specifications for reduced (<20 nanometer) line spacing.

In the present disclosure, the term polysilicon is intended to describe any type of gate material, including Hi-K dielectric metal gates, as well as any other conductive gates. “Polysilicon” is used for ease of explanation when referring to a gate.

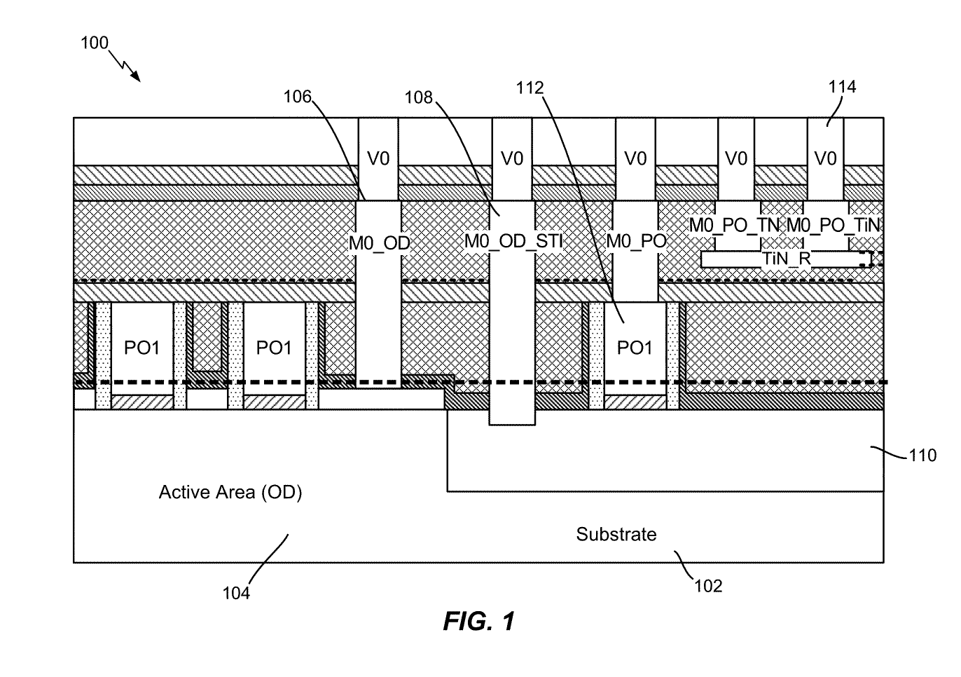

FIG. 1 illustrates a FinFET structure in accordance with an aspect of the present disclosure. A FinFET structure 100 includes a substrate 102 and an active area of oxide diffusion (OD) 104. On the substrate, a metal to diffusion (MD) interconnect 106 may be the first conductive (e.g., metal, polysilicon, or other conductive) layer on the OD 104. In addition, an MD interconnect 108 on the shallow trench isolation (STI) layer 110 is deposited through etched areas in the other layers of the FinFET structure 100. The MD interconnects 106 and 108 may be tungsten (W), copper (Cu), or other conductive materials. A polysilicon structure (PO1) 112 may also be deposited on the STI layer 110 as shown in FIG. 1. By controlling the voltages on the MD interconnects 106, 108 and the polysilicon structure 112, the circuit is controlled. Vias or contacts (V0) 114 enable access to the polysilicon structure 112 and the MD interconnects 106, 108.

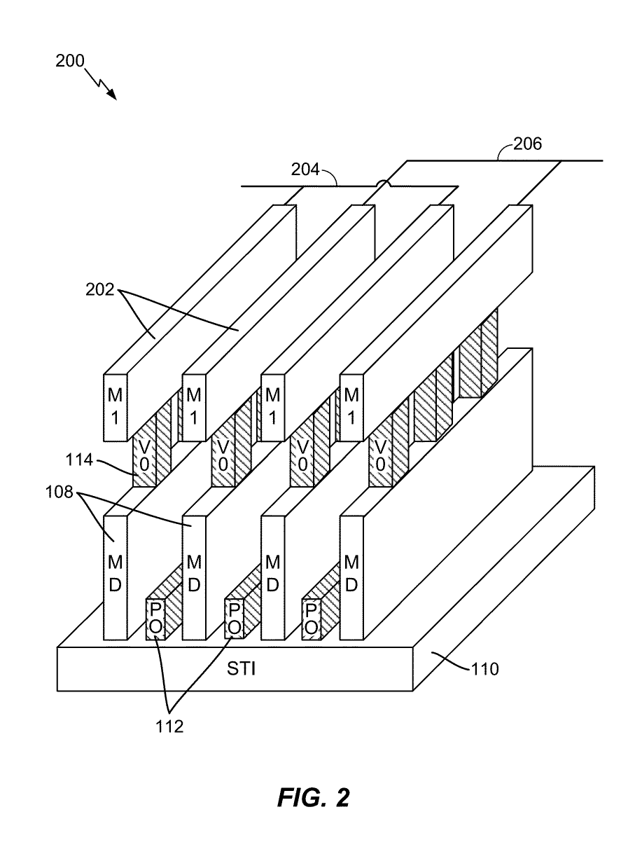

FIG. 2 illustrates a capacitor structure 200 in accordance with an aspect of the present disclosure. The MD interconnects 108 are on the STI layer 110, and interleaved with the polysilicon structures 112. First conductive layers 202 (e.g., MO are coupled to the MD interconnects 108 through vias/contacts V0 114. The first conductive layers 202 may be coupled using every-other-conductive layer connections as the capacitor terminals 204 and 206, or may be coupled in any fashion desired to create the capacitor structure 200. The capacitor terminals 204 and 206 are the terminals of the capacitor structure 200.

The polysilicon structures 112 between the MD interconnects 108 provide additional relative permittivity (K) as the dielectric material between the “plates” created by the MD interconnects 108. The effective spacing between the MD interconnects 108 with the electrically floating ones of the polysilicon structures 112 in between may be approximately thirty (30) nanometers. This effective spacing is approximately half of that in conventional capacitors. The MD interconnects overlapping height may be approximately seventy (70) nanometers. In this configuration, the capacitor structure 200 provides approximately four times the capacitance of conventional MOM capacitors. The MD interconnects 108 coupled to the first conductive layers 202 (e.g., MO through vias V0 114 help reduce the resistance and increase the quality (Q)-factor of the capacitor structure 200. The polysilicon structures 112 between the MD interconnects 108 (e.g., “fingers”) help increase the capacitance density and help satisfy the polysilicon density specifications during fabrication. The capacitor structure 200 may also be stacked with other capacitors, such as conventional capacitors.

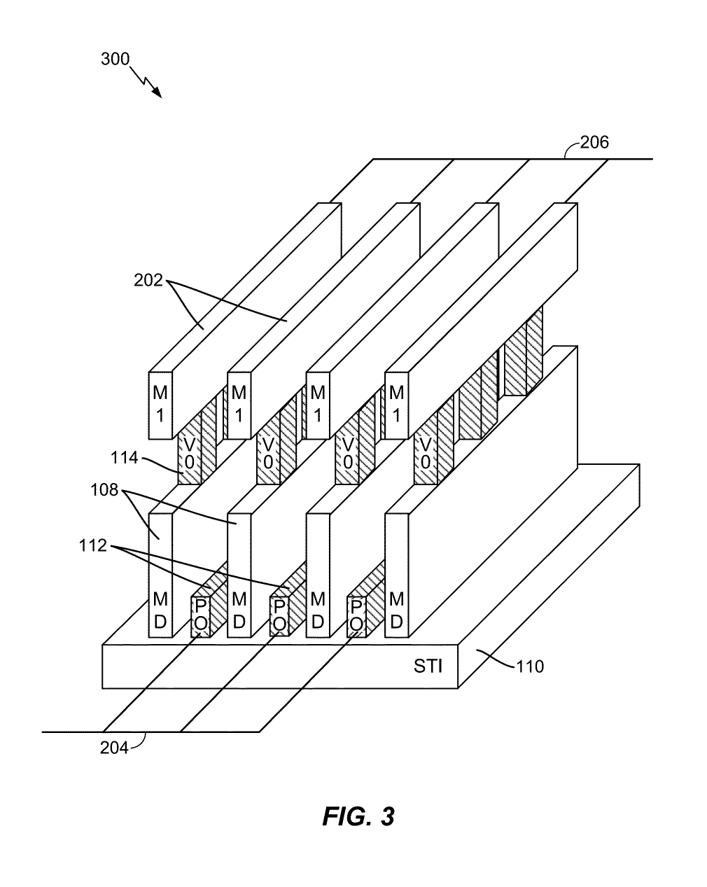

FIG. 3 illustrates a capacitor structure 300 in accordance with another aspect of the present disclosure. The MD interconnects 108 are on the STI layer 110, and, as with FIG. 2, the polysilicon structures 112 are interleaved with the MD interconnects 108. The first conductive layers 202 (e.g., MO are coupled to the MD interconnects 108 through the vias/contacts V0 114. The polysilicon structures 112 are coupled to the capacitor terminal 204. The polysilicon structures 112 structures may be coupled to the first conductive layers 202 (e.g., to a terminal conductive layer M1) through an MP interconnect(s) and a via(s) that may reside outside of the capacitor structure. The first conductive layers 202 may be coupled to the capacitor terminal 206 to create the capacitor structure 200.

In this configuration, the polysilicon structures 112 are now closer to the MD interconnects 108 to form the capacitor structure 300 with a reduced voltage tolerance. The reduced voltage tolerance is provided because the dielectric between the capacitor terminals 204 and 206 is subjected to higher electric fields per unit volume. The capacitor structure 300, however, reduces the area for a given capacitance in this aspect of the present disclosure. This effective spacing is approximately one-quarter of that in conventional capacitors. The capacitor structure 300 may also be stacked with conventional capacitors. Although shown as coupled to one side of the capacitor structures 200 and 300, the capacitor terminals 204 and 206 may be coupled elsewhere within the capacitor structures 200 and 300 without departing from the noted aspects of the present disclosure.

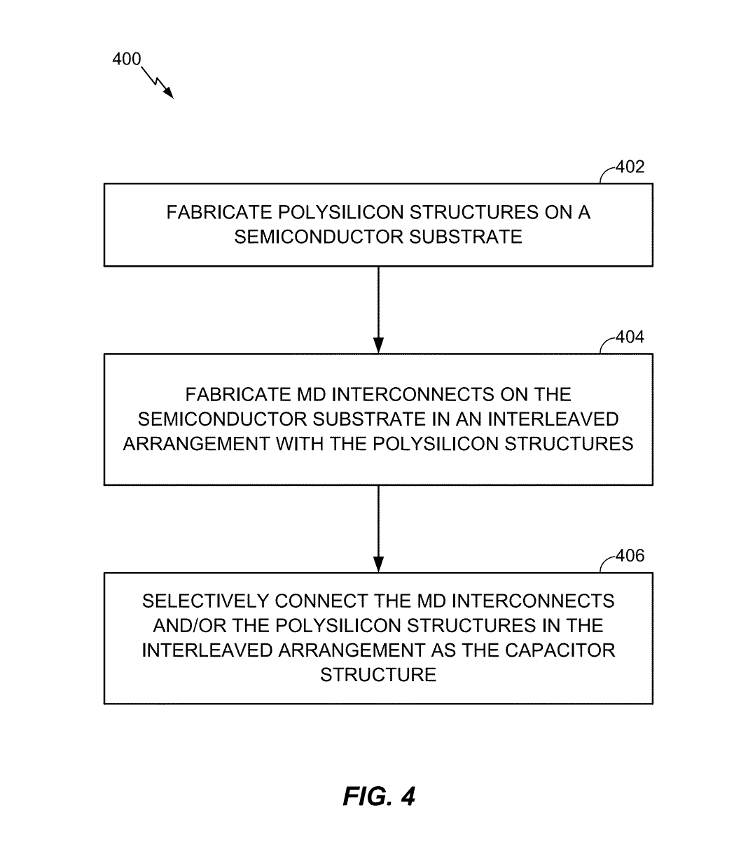

FIG. 4 is a process flow diagram illustrating a method 400 for fabricating a capacitor structure according to an aspect of the present disclosure. In block 402, polysilicon structures are fabricated on a semiconductor substrate. The polysilicon structures may be, for example, the polysilicon structures 112 shown in FIG. 2. In block 404, MD interconnects are fabricated on the semiconductor substrate. The MD interconnects may be, for example, the MD interconnects 108 shown in FIG. 2. The polysilicon structures may be disposed in an interleaved arrangement with the MD interconnects shown in FIG. 2. In block 406, the MD interconnects and/or the polysilicon structures are selectively connected in the interleaved arrangement as the capacitor structure shown in FIG. 2.

According to a further aspect of the present disclosure, a capacitor structure is described. In one configuration, the device includes polysilicon structures on a semiconductor substrate. The polysilicon structures may be the polysilicon structures 112 shown in FIG. 2. The capacitor structure also includes means for interconnecting M1 to an oxide diffusion region on the semiconductor substrate. In one configuration, the polysilicon structures are disposed in an interleaved arrangement with the interconnecting means. In this configuration, the polysilicon structures and/or the interconnecting means are selectively connected in the interleaved arrangement as the capacitor structure. The interconnecting means may be the MD interconnects 108 as shown in FIG. 2. In another aspect, the aforementioned means may be any structure or any material configured to perform the functions recited by the aforementioned means.

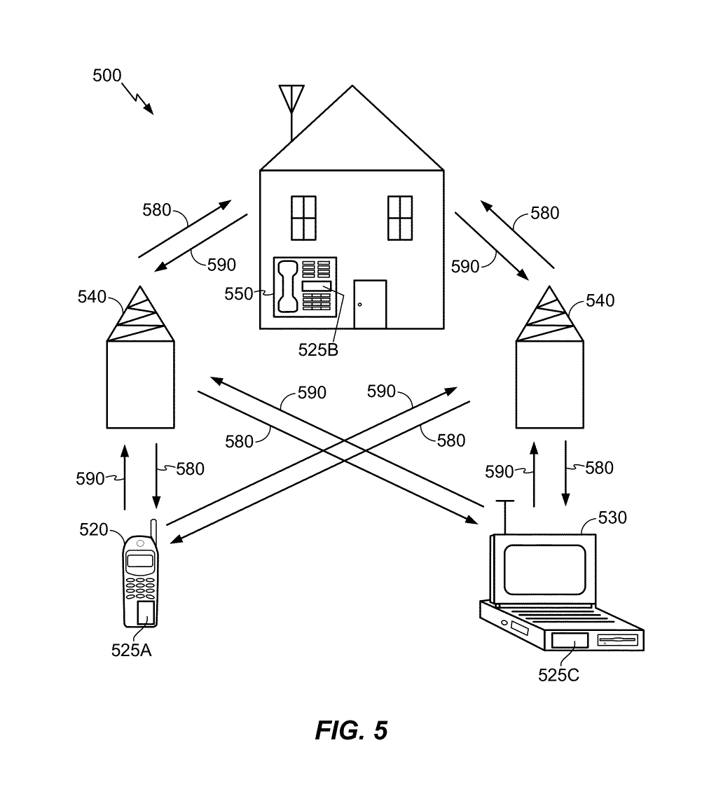

FIG. 5 is a block diagram showing an exemplary wireless communication system 500 in which an aspect of the disclosure may be advantageously employed. For purposes of illustration, FIG. 5 shows three remote units 520, 530, and 550 and two base stations 540. It will be recognized that wireless communication systems may have many more remote units and base stations. Remote units 520, 530, and 550 include IC devices 525A, 525C, and 525B that include the disclosed capacitors. It will be recognized that other devices may also include the disclosed capacitors, such as the base stations, switching devices, and network equipment. FIG. 5 shows forward link signals 580 from the base station 540 to the remote units 520, 530, and 550 and reverse link signals 590 from the remote units 520, 530, and 550 to base stations 540.

In FIG. 5, remote unit 520 is shown as a mobile telephone, remote unit 530 is shown as a portable computer, and remote unit 550 is shown as a fixed location remote unit in a wireless local loop system. For example, the remote units may be mobile phones, hand-held personal communication systems (PCS) units, portable data units such as personal data assistants, GPS enabled devices, navigation devices, set top boxes, music players, video players, entertainment units, fixed location data units such as meter reading equipment, or other devices that store or retrieve data or computer instructions, or combinations thereof. Although FIG. 5 illustrates remote units according to the aspects of the disclosure, the disclosure is not limited to these exemplary illustrated units. Aspects of the disclosure may be suitably employed in many devices, which include the disclosed capacitors.

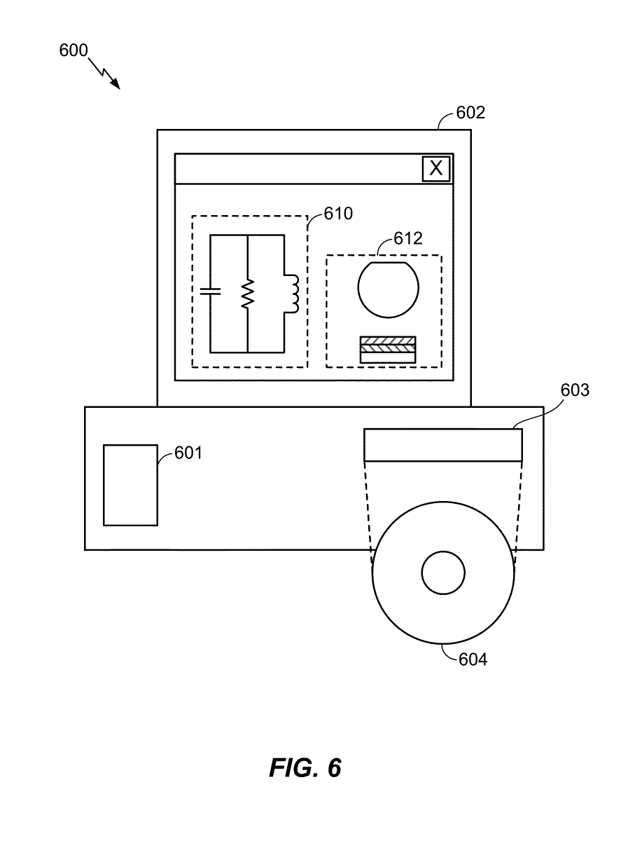

FIG. 6 is a block diagram illustrating a design workstation used for circuit, layout, and logic design of a semiconductor component, such as the capacitors disclosed above. A design workstation 600 includes a hard disk 601 containing operating system software, support files, and design software such as Cadence or OrCAD. The design workstation 600 also includes a display 602 to facilitate design of a circuit 610 or a semiconductor component 612 such as a capacitor. A storage medium 604 is provided for tangibly storing the design of the circuit 610 or the semiconductor component 612. The design of the circuit 610 or the semiconductor component 612 may be stored on the storage medium 604 in a file format such as GDSII or GERBER. The storage medium 604 may be a CD-ROM, DVD, hard disk, flash memory, or other appropriate device. Furthermore, the design workstation 600 includes a drive apparatus 603 for accepting input from or writing output to the storage medium 604.

Data recorded on the storage medium 604 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 604 facilitates the design of the circuit 610 or the semiconductor component 612 by decreasing the number of processes for designing semiconductor wafers.

According to a further aspect of the present disclosure, a capacitor structure is disclosed. In one configuration, the capacitor structure includes first means for storing charge on a semiconductor substrate. The first means may be the polysilicon structure 112. The capacitor structure also includes second means for storing charge on the semiconductor substrate. The second means may be the MD interconnects 108. In another aspect, the aforementioned means may be any module or any apparatus configured to perform the functions recited by the aforementioned means.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A method for fabricating a capacitor structure, comprising:
fabricating a plurality of polysilicon structures on a semiconductor substrate;
fabricating a plurality of M1 to diffusion (MD) interconnects on the semiconductor substrate, in which the plurality of polysilicon structures are disposed in an interleaved arrangement with the plurality of MD interconnects; and
selectively connecting the interleaved arrangement of the plurality of MD interconnects and/or the plurality of polysilicon structures as the capacitor structure.

2. The method of claim 1, in which the plurality of polysilicon structures are at a floating electrical potential.

3. The method of claim 2, in which every other interconnect in the plurality of MD interconnects is electrically coupled as a first terminal of the capacitor structure.

4. The method of claim 1, in which the plurality of MD interconnects are electrically coupled as a first terminal of the capacitor structure, and the plurality of polysilicon structures are electrically coupled as a second terminal of the capacitor structure.

5. The method of claim 1, in which the plurality of polysilicon structures and the plurality of MD interconnects are directly on a shallow trench isolation (STI) region of the semiconductor substrate.

6. The method of claim 1, further comprising fabricating a FinFET device in parallel with fabricating the capacitor structure.

7. The method of claim 6, in which a subset of the plurality of polysilicon structures comprise gate contacts.

8. The method of claim 1, in which the capacitor structure is integrated into a mobile phone, a set top box, a music player, a video player, an entertainment unit, a navigation device, a computer, a hand-held personal communication systems (PCS) unit, a portable data unit, and/or a fixed location data unit.

9. A capacitor structure, comprising:
a plurality of polysilicon structures on a semiconductor substrate; and
a plurality of M1 to diffusion (MD) interconnects on the semiconductor substrate, the plurality of polysilicon structures being disposed in an interleaved arrangement with the plurality of MD interconnects, in which the plurality of MD interconnects and/or the plurality of polysilicon structures are selectively connected in the interleaved arrangement as the capacitor structure.

10. The capacitor structure of claim 9, in which the MD interconnects are at a floating electrical potential.

11. The capacitor structure of claim 9, in which the polysilicon structures are a plate of the capacitor structure.

12. The capacitor structure of claim 9, in which every other interconnect in the plurality of MD interconnects is electrically coupled as a first terminal of the capacitor structure.

13. The capacitor structure of claim 9, in which the plurality of MD interconnects are electrically coupled as a first terminal of the capacitor structure, and the plurality of polysilicon structures are electrically coupled as a second terminal of the capacitor structure.

14. The capacitor structure of claim 9, in which the plurality of polysilicon structures and the plurality of MD interconnects are directly on a shallow trench isolation (STI) region of the semiconductor substrate.

15. The capacitor structure of claim 9, further comprising a FinFET device.

16. The capacitor structure of claim 9, in which a subset of the plurality of polysilicon structures comprise gate contacts.

17. The capacitor structure of claim 9, integrated into a mobile phone, a set top box, a music player, a video player, an entertainment unit, a navigation device, a computer, a hand-held personal communication systems (PCS) unit, a portable data unit, and/or a fixed location data unit.

18. A method for fabricating a capacitor structure, comprising the steps of:
the step for fabricating a plurality of polysilicon structures on a semiconductor substrate;
the step for fabricating a plurality of M1 to diffusion (MD) interconnects on the semiconductor substrate, in which the plurality of polysilicon structures are disposed in an interleaved arrangement with the plurality of MD interconnects; and
the step for selectively connecting the interleaved arrangement of the plurality of MD interconnects and/or the plurality of polysilicon structures as the capacitor structure.

19. The method of claim 18, in which the capacitor structure is integrated into a mobile phone, a set top box, a music player, a video player, an entertainment unit, a navigation device, a computer, a hand-held personal communication systems (PCS) unit, a portable data unit, and/or a fixed location data unit.

20. A capacitor structure, comprising:
a plurality of polysilicon structures on a semiconductor substrate; and
means for interconnecting a conducting layer to an oxide diffusion region on the semiconductor substrate, the plurality of polysilicon structures being disposed in an interleaved arrangement with the interconnecting means, in which the plurality of polysilicon structures and/or the interconnecting means are selectively connected in the interleaved arrangement as the capacitor structure.

21. The capacitor structure of claim 20, in which the polysilicon structures are at a floating electrical potential.

22. The capacitor structure of claim 20, in which the polysilicon structures are a plate of the capacitive structure.

23. The capacitor structure of claim 20, in which every other interconnecting means is electrically coupled as a first terminal of the capacitor structure.

24. The capacitor structure of claim 20, integrated into a mobile phone, a set top box, a music player, a video player, an entertainment unit, a navigation device, a computer, a hand-held personal communication systems (PCS) unit, a portable data unit, and/or a fixed location data unit.
